(19) United States
(12) Patent Application Publication
(10) Pub. No.: US 2015/0333209 A1
(43) Pub. Date: Nov. 19, 2015

(54) STACKING STRUCTURE OF A PHOTOELECTRIC DEVICE

(71) Applicant: NATIONAL SUN YAT-SEN UNIVERSITY, Kaohsiung City (TW)

(72) Inventors: I-Kai Lo, Kaohsiung City (TW); Cheng-Hung Shih, Kaohsiung City (TW); Bae-Heng Tseng, Kaohsiung City (TW)

(21) Appl. No.: 14/627,563

(22) Filed: Feb. 20, 2015

(30) Foreign Application Priority Data
May 15, 2014 (TW) 103117189

(51) Int. Cl. H01L 31/0725; H01L 31/0352

(52) U.S. Cl. CPC H01L 31/0725; H01L 31/0352

(57) ABSTRACT

A stacking structure of a photoelectric device includes a base, a first conducting layer, a first semiconductor layer, a second semiconductor layer, a second conducting layer and two electrodes. The base is essentially made of a light-permeable material. The first conducting layer is arranged on the base and essentially made of a light-permeable, non-metal material. The first semiconductor layer is arranged on the first conducting layer and essentially made of a ternary compound with chalcopyrite phase. The second semiconductor layer is arranged on the first semiconductor layer. The second conducting layer is arranged on the second semiconductor layer and essentially made of a light-permeable semiconductor material different from the light-permeable, non-metal material of the first conducting layer. The two electrodes are respectively arranged on the first and second conducting layers.

### BACKGROUND OF THE INVENTION

1. Field of the Invention

The present invention generally relates to a stacking structure of a photoelectric device and, more particularly, to a stacking structure of a photoelectric device capable of converting light energy into electricity.

2. Description of the Related Art

Photoelectric devices such as solar cells or light detectors are capable of converting light energy into electricity for further storage (solar cells) or for detecting light (light detectors). As an example of solar cells, the commercial solar cells are usually made of silicon. However, due to the indirect bandgap of silicon, the converting efficiency of the produced photoelectric device is insufficient and results in a thermal loss. This problem can be overcome by using another type of material with direct bandgap, such as Copper Indium Selenide (CuInSe₂).

A conventional CuInSe₂ solar cell is formed by growing molybdenum (Mo) metal on a glass base, growing CuInSe₂ on Mo, growing CdS on CuInSe₂ and finally growing ZnO on CdS. In this arrangement, the received solar energy of the solar cell can be converted into electricity via the photovoltaic effect.

However, as a disadvantage, the narrow bandgap of the silicon contained in the glass base of the conventional solar cell tends to absorb the light energy. In addition, as another disadvantage, the light at one side of the photoelectric device adjacent to the glass base cannot be received by the solar cell since the molybdenum metal is light-impermeable and will prevent passage of the light. As such, only the light at another side of the photoelectric device opposite to the glass base can penetrate into the solar cell, leading to a low power generating efficiency of the solar cell.

In light of the above, it is necessary to improve the conventional solar cell.

### SUMMARY OF THE INVENTION

It is therefore the objective of this disclosure to provide a stacking structure of a photoelectric device that allows the light at the side of the photoelectric device adjacent to the base to penetrate said element.

It is another objective of this disclosure to provide a stacking structure of a photoelectric device that reduces the amount of light absorbed at the side of the photoelectric device adjacent to the base.

In an embodiment, a stacking structure of a photoelectric device includes a base, a first conducting layer, a first semiconductor layer, a second semiconductor layer, a second conducting layer and two electrodes. The base is essentially made of a light-permeable material. The first conducting layer is arranged on the base and essentially made of a light-permeable, non-metal material. The first semiconductor layer is arranged on the first conducting layer and essentially made of a ternary compound with chalcopyrite phase. The second semiconductor layer is arranged on the first semiconductor layer. The second conducting layer is arranged on the second semiconductor layer and essentially made of a light-permeable semiconductor material different from the light-permeable, non-metal material of the first conducting layer. The two electrodes are respectively arranged on the first and second conducting layers.

In a form shown, the first conducting layer is essentially made of a light-permeable III-nitride.

In the form shown, the light-permeable III-nitride is gallium nitride or aluminum nitride.

In the form shown, the light-permeable III-nitride includes a group 1 element, a group 3 element and a group 6 element with a mole ratio of 1:1:2. The group 1 element is Copper, the group 3 element is Indium, Gallium or Aluminum, and the group 6 element is Selenium or Sulphur.

In the form shown, the second semiconductor layer is essentially made of Cadmium Sulphide, Zinc Sulphide, Zinc Hydroxide or Indium Sulphide.

In the form shown, the second conducting layer is essentially made of Zinc Oxide or Indium Tin Oxide.

In the form shown, the base is essentially made of glass or sapphire.

In the form shown, the stacking structure of the photoelectric device further includes a buffer layer arranged between the first and second semiconductor layers.

In the form shown, the buffer layer is essentially made of Indium Nitride.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a cross sectional view of a stacking structure of a photoelectric device according to a first embodiment of the invention.

FIG. 2 is a cross sectional view of a stacking structure of a photoelectric device according to a second embodiment of the invention.

FIG. 3a shows a bright field image of the stacking structure of the photoelectric device when the first semiconductor layer of the stacking structure is CuInSe₂(112).

FIG. 3b shows a SAD image of the stacking structure of the photoelectric device when the first semiconductor layer is CuInSe₂.

FIG. 3c shows a SAD image of the stacking structure of the photoelectric device when the first semiconductor layer is CuInSe₂ and the first conducting layer is GaN.

FIG. 3d shows a SAD image of the stacking structure of the photoelectric device when the first conducting layer is GaN.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

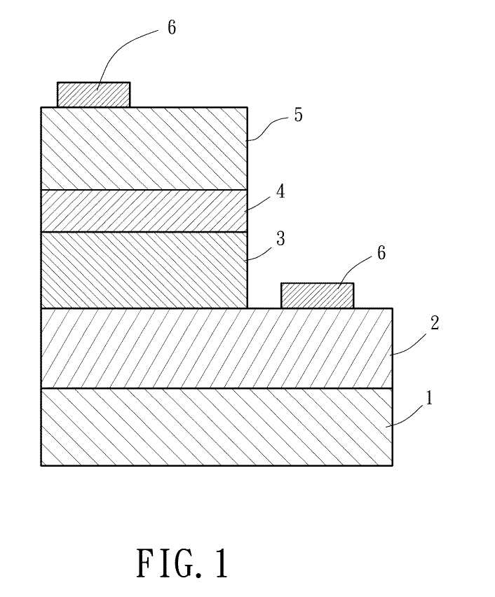

FIG. 1 is a cross sectional view of a stacking structure of a photoelectric device according to a first embodiment of the invention. The stacking structure includes a base 1, a first conducting layer 2, a first semiconductor layer 3, a second semiconductor layer 4, a second conducting layer 5 and two electrodes 6. The first conducting layer 2, the first semiconductor layer 3, the second semiconductor layer 4 and the second conducting layer 5 are sequentially stacked on the base 1. The two electrodes 6 are arranged on the first conducting layer 2 and the second conducting layer 5, respectively.

Please refer to FIG. 1 again, the base 1 may be made of a light-permeable material such as glass or sapphire, such that the first conducting layer 2 can be epitaxially formed on the base 1. In the embodiment, the base 1 is made of glass, but is not limited thereto.

Referring to FIG. 1, the first conducting layer 2 is arranged between the base 1 and the first semiconductor layer 3. The first conducting layer 2 is essentially made of a light-permeable non-metal material, such as light-permeable III-nitride (group 3 Nitride) semiconductor material. The III-nitride may preferably be Gallium Nitride (GaN) or Aluminum Nitride (MN) that appears to be transparent. However, the type of the III-nitride is not limited to the above. The light at the side of the photoelectric device adjacent to the base 1 may penetrate into the first semiconductor layer 3, and the electricity generated by the stacking structure of the photoelectric device can be outputted. Moreover, the III-nitride may increase the mobility of electrons, and its direct bandgap may improve the photoelectric conversion efficiency of the photoelectric device. In this embodiment, the first conducting layer 2 is GaN and may be epitaxially formed. However, this is not taken as a limited sense. In the above arrangement, since the single-crystal GaN is light-permeable, the light at the side of the photoelectric device adjacent to the base 1 can penetrate into the first semiconductor layer 3 while the reflection of light is prevented and the amount of the light received is increased. Furthermore, the direct bandgap of GaN is able to increase the amount of the outputted electricity of the solar cell or improve the ability of the battery to detect the light.

Please refer to FIG. 1 again, the first semiconductor layer 3 is arranged between the first conducting layer 2 and the second semiconductor layer 4. The first semiconductor layer 3 forms a P-N junction and may consist of P-type semiconductor material. The first semiconductor layer 3 may preferably be a ternary compound with chalcopyrite phase. The ternary compound consists of a group 1 element, a group 3 element and a group 6 element with a mole ratio of 1:1:2 (I-III-VI₂). The group 1 element may be Copper (Cu), the group 3 element may be Indium (In), Gallium (Ga) or Aluminum (Al), and the group 6 element may be Selenium (Se) or Sulphur (S). However, this is not to be taken as a limited sense. This arrangement improves the arrangement regularity of the interface between the first conducting layer 2 and the first semiconductor layer 3. In this embodiment, Molecular Beam Epitaxy (MBE) may be used to form the first semiconductor layer 3 by epitaxially growing the ternary compound with chalcopyrite phase on the III-nitride. Such ternary compound may be Copper Indium Selenide (CuInSe₂, CISe), Copper Gallium Selenide (CuGaSe₂), Copper Aluminum Selenide (CuAlSe₂), Copper Indium Sulphide (CuInS₂), Copper Gallium Sulphide (CuGaS₂) and Copper Aluminum Sulphide (CuAlS₂, CIS). In addition, the first semiconductor layer 3 may also be a quaternary compound with chalcopyrite phase, such as Cu(In,Ga)Se₂, Cu(Al,In)Se₂ or Cu(Al,Ga)Se₂. However, this is not taken as a limited sense. As an example, when CuInSe₂ is grown on single-crystal GaN, impurities will not be generated at the interface between GaN and CuInSe₂ due to the chemical reaction therebetween. This improves not only the electricity generation efficiency of the photoelectric device but also the reliability of said element.

Referring to FIG. 1 again, the second semiconductor layer 4 is arranged between the first semiconductor layer 3 and the second conducting layer 5. The second semiconductor layer 4 may consist of N-type semiconductor material, such as Cadmium Sulphide (CdS), Zinc Sulphide (ZnS), Zinc Hydroxide (ZnOH) or Indium Sulphide (InS). In this embodiment, the second semiconductor layer 4 is made of CdS and is formed on the first semiconductor layer 3 by chemical bath and sputting. However, this is not taken as a limited sense.

Referring to FIG. 1 again, the second conducting layer 5 is arranged on the second semiconductor layer 4 and is preferably made of light-permeable semiconductor material such as Zinc Oxide (ZnO) or Indium Tin Oxide (ITO). As such, the light at another side of the photoelectric device opposite to the base 1 will be able to penetrate into the second semiconductor layer 4, and the electricity generated by the stacking structure of the photoelectric device can be outputted. However, the second semiconductor layer 4 is made of different material from the first conducting layer 2. In this embodiment, the second conducting layer 5 is made of ZnO and is formed on the second semiconductor layer 4 by chemical bath and sputting. However, this is not to be taken as a limited sense. ZnO not only allows the external light to penetrate into the second semiconductor layer 4 but also prevents the reflection of the light, which avoids the scattering of the light. As such, the amount of light that can be utilized is increased.

Referring to FIG. 1 again, the two electrodes 6 are preferably made of material with excellent electricity conductivity, such as Aurum (Au), Platinum (pt) or Aluminum (Al). The two electrodes 6 are respectively arranged on the first conducting layer 2 and the second conducting layer 5 in order to conduct the electricity of the first conducting layer 2 and the second conducting layer 5. In this embodiment, the two electrodes 6 are made of aluminum. However, this is not to be taken as a limited sense.

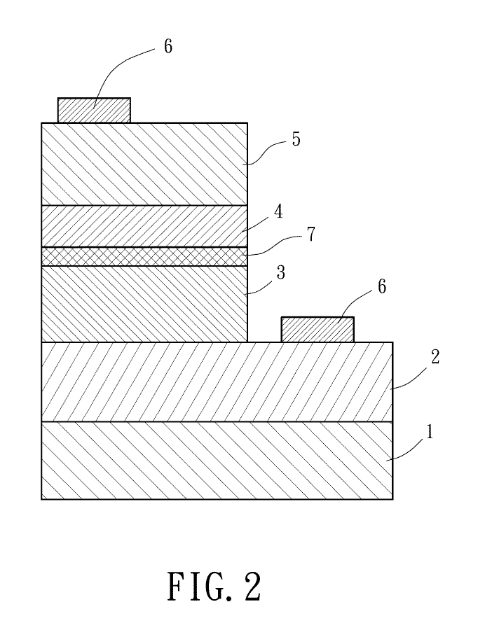

FIG. 2 is a cross sectional view of a stacking structure of a photoelectric device according to a second embodiment of the invention. The stacking structure of the second embodiment further comprises a buffer layer 7 in addition to the base 1, the first conducting layer 2, the first semiconductor layer 3, the second semiconductor layer 4, the second conducting layer 5 and the electrodes 6 as presented in the first embodiment. The buffer layer 7 is arranged between the first semiconductor layer 3 and the second semiconductor layer 4. The buffer layer 7 essentially consists of Indium Nitride (InN) and serves as a light absorbing layer (the bandgap of InN is 0.7 eV and the bandgap of CISe is 1.04 eV). As such, the far infrared energy in the sunlight can be absorbed, increasing the amount of the absorbed light. In this embodiment, the buffer layer 7 is epitaxially formed, but is not limited thereto.

Referring to FIGS. 1 and 2, when in use, the light at the side of the photoelectric device adjacent to the base 1 can penetrate into the first semiconductor layer 3 via the base 1 and the first conducting layer 2, and the light at the other side of the photoelectric device opposite to the base 1 can penetrate into the second semiconductor layer 4 via the second conducting layer 5 and the buffer layer 7. Thus, the second semiconductor layer 4 and the first semiconductor layer 3 are able to convert the light energy into electricity under the photoelectric effect, as it can be readily appreciated by the skilled persons. The generated electricity can be outputted by the two electrodes 6. Accordingly, the photoelectric device can serve as a solar cell or a light detector.

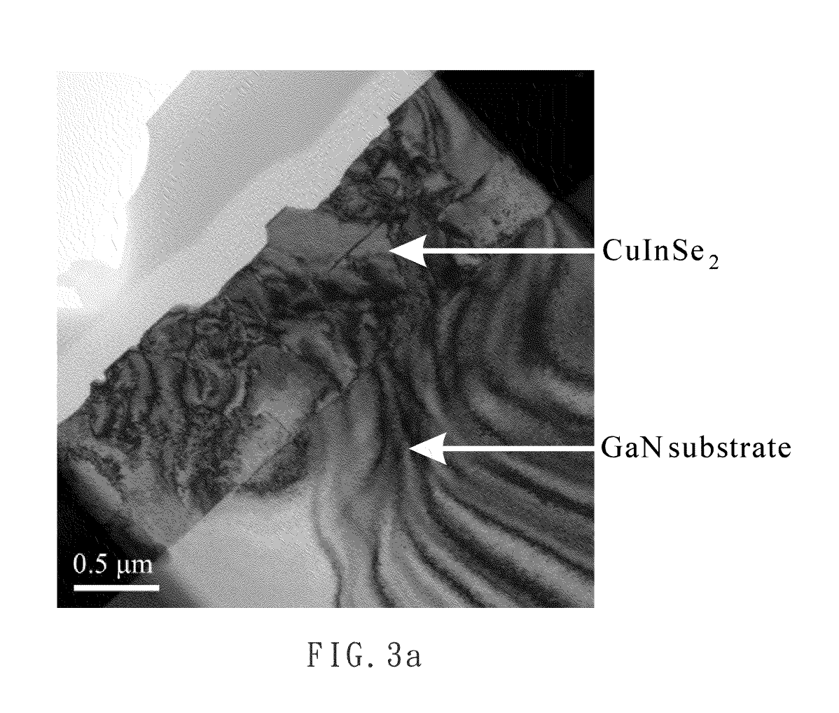

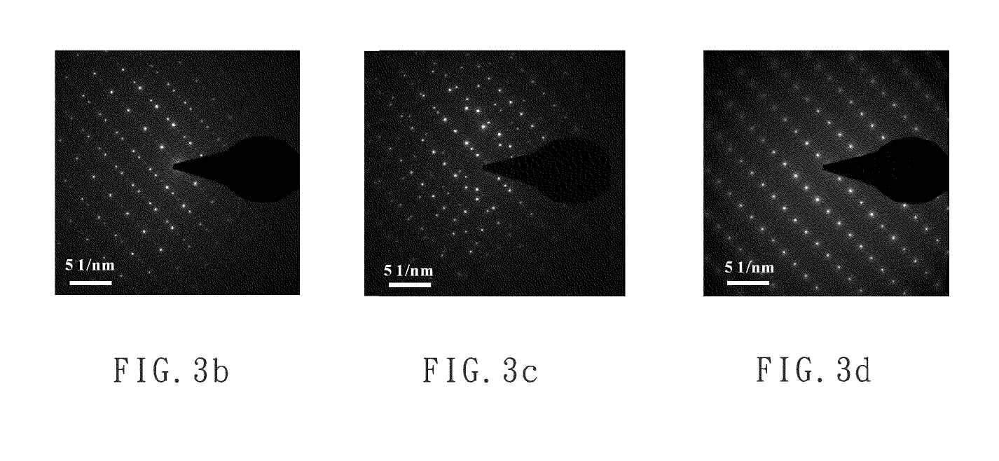

FIG. 3a shows a bright field image of the stacking structure of the photoelectric device when the first semiconductor layer is CuInSe₂(112). FIG. 3b shows a selected area diffraction (SAD) image of the stacking structure of the photoelectric device when the first semiconductor layer is CuInSe₂. FIG. 3c shows a SAD image of the stacking structure of the photoelectric device when the first semiconductor layer is CuInSe₂ and the first conducting layer is GaN. FIG. 3d shows a SAD image of the stacking structure of the photoelectric device when the first conducting layer is GaN. It can be known from FIGS. 3b and 3c that the diffraction points of the SAD image of the interface between CuInSe₂ and GaN are of regular arrangement. Thus, it is proven that CuInSe₂ can be epitaxially grown on GaN. In this regard, the CuInSe/GaN interface does improve the photoelectric efficiency. As compared with the conventional photoelectric device, the photoelectric device of the invention has a higher photoelectric conversion efficiency.

It is noted that since the lattice fault (defects) between the crystal materials causes a leakage current of the element, it becomes the main factor that affects the performance of the photoelectric semiconductor. The lattice fault is caused by lattice mismatch and crystal system mismatch. One of the examples of the lattice mismatch is that when GaN is grown on a sapphire base, there exists a lattice mismatch between the lattices of the sapphire base and GaN. Although both the sapphire base and GaN are hexagonal, the lattice mismatch still exists due to different lattice sizes therebetween. On the other hand, one of the examples of the crystal system mismatch is that when GaN is grown on the silicon base, there exists a mismatch between the crystal systems of the silicon base and GaN since the silicon base is of cubic crystal system and GaN is of hexagonal crystal system. This is explained in the paper entitled “Structural and electrical characterization of GaN thin film on Si (100)”, as published by Gajanan Niranjan Chaudhari, Vijay Ramkrishna Chinchamalatpure and Sharada Arvind Ghosh in American Journal of Analytical Chemistry, 2011, 2, 984-988. Furthermore, the crystal system mismatch often comes with lattice mismatch. It can be known from semiconductor physics theory that the epitaxial operation will not be able to be smoothly performed due to the lattice fault caused by large lattice mismatch rate. For example, the lattice mismatch rate between GaN and CuInSe₂ is larger than 28.5%, leading to a high potential of failure of the epitaxial operation. However, it has been proven through experiments that the application is able to reduce the lattice mismatch rate from 28.5% (theoretical value) to 2.8% (actual value) when CuInSe₂(112) is combined with GaN(0001). In light of this, it becomes possible to grow CuInSe₂(112) on GaN(0001), which overthrows the traditional perception that the epitaxial operation cannot be performed under a large lattice mismatch rate. In this regard, the GaN(0001) material appears to be transparent, which does solve the problem of having difficulty in receiving the light from the side of the photoelectric devices adjacent to the base.

Based on the above disclosure, the stacking structure of the photoelectric device is characterized as follows. The stacking structure comprises the base, the first conducting layer, the first semiconductor layer, the second semiconductor layer, the second conducting layer and two electrodes. The base is essentially made of a light-permeable material. The first conducting layer is arranged on the base and may be made of light-permeable, non-metal material. The first semiconductor layer is arranged on the first conducting layer. The first semiconductor layer may preferably be the ternary compound with chalcopyrite phase. The second conducting layer is arranged on the second semiconductor layer and may be essentially made of a light-permeable semiconductor material. The second conducting layer is made of different material from the first conducting layer. The two electrodes are arranged on the first conducting layer and the second conducting layer, respectively. A buffer layer may be arranged between the first and second semiconductor layers. In the above arrangement, the stacking structure of the photoelectric device is able to receive the lights from not only the side of the photoelectric device adjacent to the base but also from the other side of the photoelectric device opposite to the base. This effectively reduces the amount of light absorbed at the side of the photoelectric device adjacent to the base, thereby improving the electricity generation efficiency and ensuring the performance of the photoelectric device.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A stacking structure of a photoelectric device comprising:
a base essentially made of a light-permeable material;
a first conducting layer arranged on the base and essentially made of a light-permeable, non-metal material;
a first semiconductor layer arranged on the first conducting layer and essentially made of a ternary compound with chalcopyrite phase;
a second semiconductor layer arranged on the first semiconductor layer;
a second conducting layer arranged on the second semiconductor layer and essentially made of a light-permeable semiconductor material different from the light-permeable, non-metal material of the first conducting layer; and
two electrodes respectively arranged on the first and second conducting layers.

2. The stacking structure of the photoelectric device as claimed in claim 1, wherein the first conducting layer is essentially made of a light-permeable III-nitride.

3. The stacking structure of the photoelectric device as claimed in claim 2, wherein the light-permeable III-nitride is gallium nitride or aluminum nitride.

4. The stacking structure of the photoelectric device as claimed in claim 1, wherein the light-permeable III-nitride comprises a group 1 element, a group 3 element and a group 6 element with a mole ratio of 1:1:2, wherein the group 1 element is Copper, the group 3 element is Indium, Gallium or Aluminum, and the group 6 element is Selenium or Sulphur.

5. The stacking structure of the photoelectric device as claimed in claim 1, wherein the second semiconductor layer is essentially made of Cadmium Sulphide, Zinc Sulphide, Zinc Hydroxide or Indium Sulphide.

6. The stacking structure of the photoelectric device as claimed in claim 1, wherein the second conducting layer is essentially made of Zinc Oxide or Indium Tin Oxide.

7. The stacking structure of the photoelectric device as claimed in claim 1, wherein the base is essentially made of glass or sapphire.

8. The stacking structure of the photoelectric device as claimed in claim 1, further comprising a buffer layer arranged between the first and second semiconductor layers.

9. The stacking structure of the photoelectric device as claimed in claim 8, wherein the buffer layer is essentially made of Indium nitride.
